(19) United States
(12) Patent Application Publication
(10) Pub. No.: US 2012/0061810 A1
(43) Pub. Date: Mar. 15, 2012

(54) LED LEAD FRAME HAVING DIFFERENT MOUNTING SURFACES

(75) Inventors: CHENG-CHING CHIEN, New Taipei (TW); BEEN-YANG LIAW, New Taipei (TW)

(73) Assignee: HON HAI PRECISION INDUSTRY CO., LTD., New Taipei (TW)

(21) Appl. No.: 13/231,973

(22) Filed: Sep. 14, 2011

(30) Foreign Application Priority Data
Sep. 14, 2010 (TW) 099217734

(51) Int. Cl. H01L 23/495

(52) U.S. Cl. 257/668; 257/E23.031

(57) ABSTRACT

An LED lead frame comprises an insulative housing including a top surface, a bottom surface, and four side surfaces connected the top surface and the bottom surface, and a cavity recessed from the top surface. A pair of conductive leads each has a portion embedded into the insulative housing and another portion exposed out of the insulative housing. The another portion includes an end portion extending downwardly along one of the side surface, a bottom soldering portion extending continuously from the end portion along the bottom surface, and a pair of side soldering portions extending upwardly from two ends of the bottom soldering portion along another two opposite side surfaces. The bottom soldering portion and the side soldering portions can be used as an alternative mounting surface.

### BACKGROUND OF THE INVENTION

1. Field of the Invention

The present invention relates to an LED lead frame, and more particularly to an LED lead frame having a conductive lead with a bottom soldering surface and a side soldering surface which can be used as an alternative mounting surface.

2. Description of Related Art

U.S. Pat. No. 6,486,543 issued to Sano et al. on Nov. 26, 2002 discloses a semiconductor device including a semiconductor chip, a first lead connected to an electrode of the semiconductor chip, a second lead connected to another electrode of the semiconductor chip, and a resin package sealing the semiconductor chip, and inner terminal of the first lead, and an inner terminal of the second lead. The resin package includes a first to a fourth side surfaces, an upper surface and a bottom surface. Each of the first and the second leads includes outer terminals extending along the first side surface and second side surface, and then along the bottom surface of the resin package.

The above first and second leads extending out of the resin package are divided into two pieces respectively along the first and the second side surfaces such that reduce the intensity of the first and the second leads.

Therefore, an improved semiconductor device is needed.

### SUMMARY OF THE INVENTION

An object of the present invention is to provide an LED lead frame having a conductive lead which includes a bottom soldering surface and a side soldering surface as a mounting surface, and the conductive lead having enough intensity.

To achieve the aforementioned object, an LED lead frame comprises an insulative housing including a top surface, a bottom surface, and four side surfaces connected the top surface and the bottom surface, and a cavity recessed from the top surface. A pair of conductive leads each has a portion embedded into the insulative housing and another portion exposed out of the insulative housing. The another portion includes an end portion extending downwardly along one of the side surface, a bottom soldering portion extending continuously from the end portion along the bottom surface, and a pair of side soldering portions extending upwardly from two ends of the bottom soldering portion along another two opposite side surfaces.

To further achieve the aforementioned object, an LED lead frame comprises an insulative housing and a pair of conductive leads. Each conductive lead has a portion embedded into the insulative housing and another portion exposed out of the housing. The another portion bends three times to form an end portion, a bottom soldering portion, and a pair of side soldering portions.

Other objects, advantages and novel features of the invention will become more apparent from the following detailed description of a preferred embodiment when taken in conjunction with the accompanying drawings.

### BRIEF DESCRIPTION OF THE DRAWINGS

FIG. 1 is an assembly, perspective view of a LED lead frame in accordance with the present invention;

FIG. 2 is a side view of the LED lead frame in FIG. 1;

FIG. 3 is a bottom view of the LED lead frame in FIG. 1;

FIG. 4 is an exploded, perspective view of the LED lead frame; and

FIG. 5 is another exploder, perspective view of the LED lead frame.

### DETAILED DESCRIPTION OF THE INVENTION

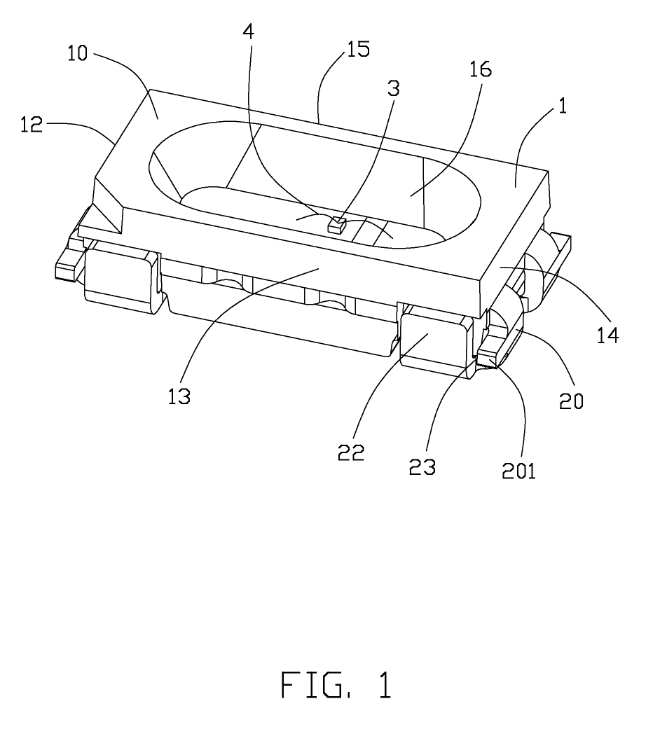

Referring to FIG. 1, an LED lead frame made in accordance with a preferable embodiment of the present invention is shown. The LED lead frame is used to connect an LED chip 3 and includes an insulative housing 1 and a pair of conductive leads 2 mounted with the insulative housing 1.

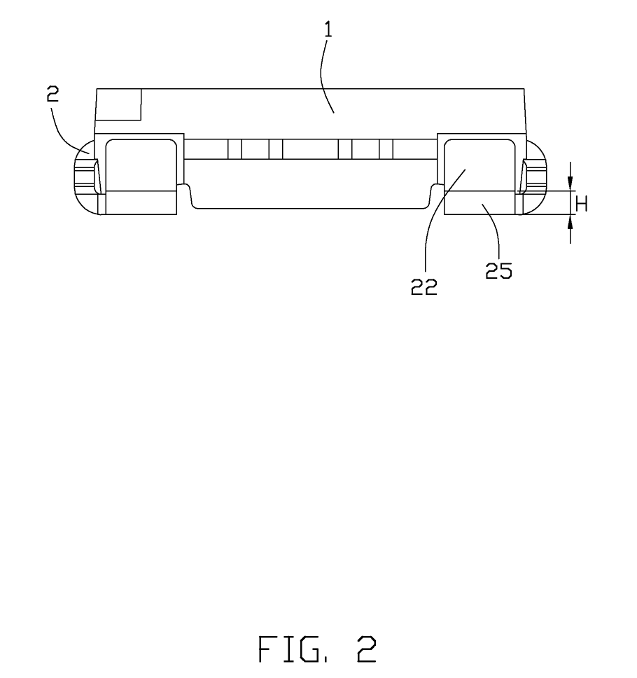

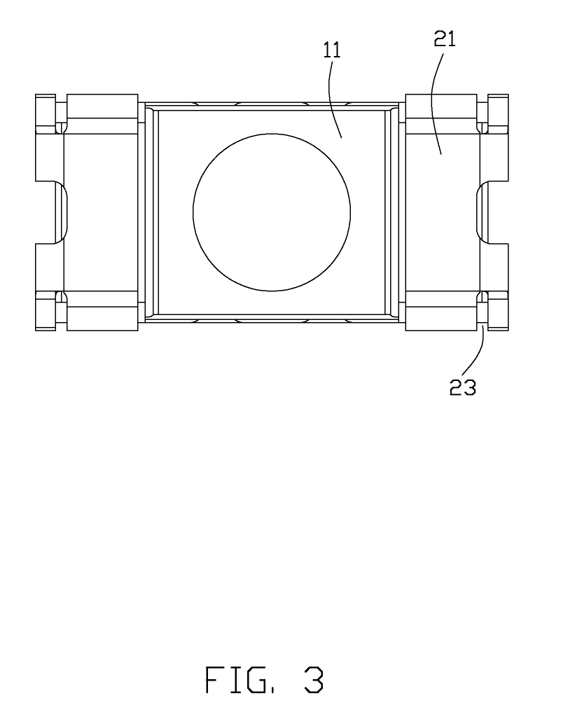

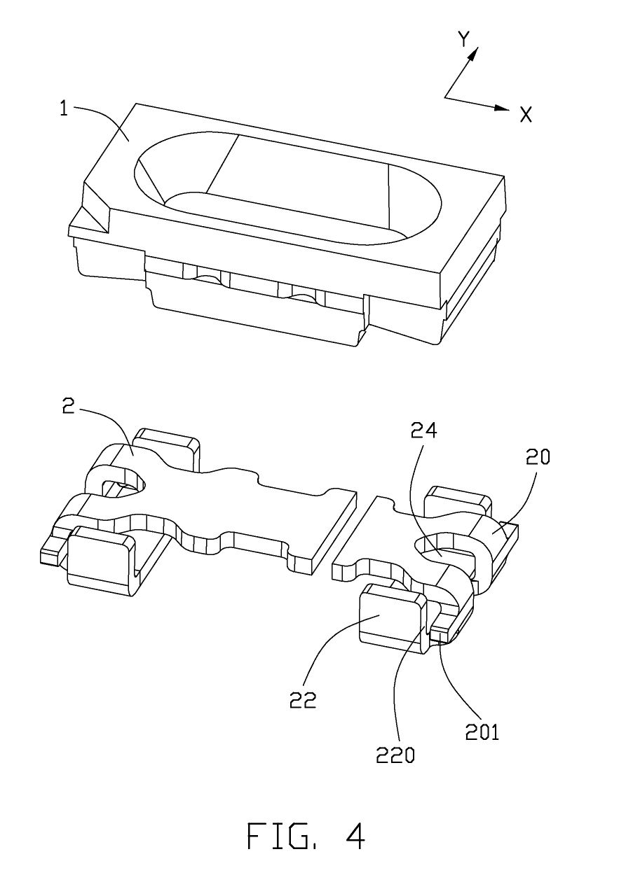

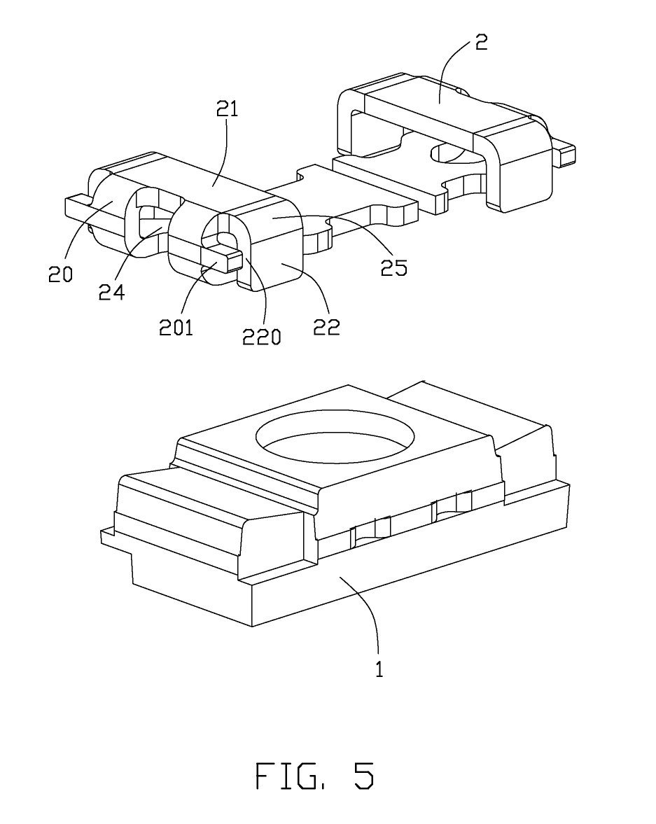

Referring to FIG. 1 to FIG. 5, the insulative housing 1 has a rectangular shape with four side surfaces 12-15, a top surface 10 and a bottom surface 11, and is molded with the conductive leads 2 by injection-molding technology. An X direction and a Y direction are defined at the center of the insulative housing 1, wherein the X direction extends along a longitudinal side of the insulative housing 1 and the Y direction extends along a traversal side of the insulative housing 1. The four side surfaces 12-15 comprises a first and a third side surfaces 12, 14 arranged perpendicular to the X direction, and a second and a fourth side surfaces 13, 15 arranged perpendicular to the Y direction. A cavity 16 is recessed into the top surface 10 of the insulative housing 1 such that a concave space is defined.

Continual referring to FIG. 1 to FIG. 5, each of the two conductive leads 2 are partially embedded in the insulative housing 1 with one end thereof exposed in a bottom of the cavity 16. The LED chip 3 is disposed on one of the conductive leads 2 in the cavity 16 and electrically connects with the two conductive leads 2 by two wires 4. Each conductive lead 2 includes an end portion 20 which is formed by the other end of the conductive lead 2 extending downwardly along the first side surface 12 or the third side surface 14 of the insulative housing 1. Bottom soldering portions 21 extend continuously from respective end portions 20 along the bottom surface 11 of the insulative housing 1 and perpendicular to the X direction. Side soldering portions 22 extend upwardly from respective bottom soldering portions 21 along the second side surface 13 and the forth side surface 15.

The side soldering portions 22 are disposed respectively near the first side surface 12 and the third side surface 14. A pair of tabs 201 extends from one end portion 20 and perpendicular to the X direction. So a small slot 23 is defined between the tab 201 and respective sides 220 of the side soldering portions 22 for enhancing siphon effect when the LED lead frame is soldered by the side soldering portions 22. When the side soldering portions 22 are soldered on a board, the solder climbs into the slot 23 and adhibits the sides 220 of the side soldering portions 22 which can enhance the intensity of soldering. In addition, a curved portion 25 is formed between the side soldering portion 22 and the bottom soldering portion 21, and the curved portion 25 from the highest to the lowest point having a height H is between 0.1-0.3 millimeter which also can enhance the siphon effect and the intensity of soldering.

In the present invention, the side soldering portions 22 and the bottom soldering portions 21 both can be alternative as the mounting surfaces. Each conductive lead 2 is configured as one piece extending out of the insulative housing 1 so that the conductive lead 2 is not easy to snap. The conductive lead 2 extends perpendicular to the Y direction so as to extend the length that the water vapor passes into the cavity 16 of the insulative housing 1. To further prevent the penetration of the water vapor, each conductive lead 2 defines a through hole 24 in the insulative housing 1 to extend the using life of the LED lead frame.

Although the present invention has been described with reference to particular embodiments, it is not to be construed as being limited thereto. Various alterations and modifications can be made to the embodiments without in any way departing from the scope or spirit of the present invention as defined in the appended claims.

What is claimed is:

1. An LED lead frame comprising:
an insulative housing including a top surface, a bottom surface, and a pair of opposite side surfaces connected the top surface and the bottom surface, and a cavity recessed from the top surface;
a pair of conductive leads each having a portion embedded into the insulative housing and another portion exposed out of the insulative housing;
the another portion including an end portion extending downwardly along one of the side surface, a bottom soldering portion extending continuously from the end portion along the bottom surface, and a pair of side soldering portions extending upwardly from two ends of the bottom soldering portion along another two opposite side surfaces.

2. The LED lead frame as claimed in claim 1, wherein a pair of tabs extend from two opposite sides of the end portion and each is formed with a slot with the respective side soldering portion.

3. The LED lead frame as claimed in claim 1, wherein a curved portion is formed between the side soldering portion and the bottom soldering portion, and the curved portion from the highest to the lowest point having a height is between 0.1-0.3 millimeter.

4. The LED lead frame as claimed in claim 1, wherein each conductive lead defines a through hole partially embedded in the insulative housing to extend the using life of the LED lead frame.

5. An LED lead frame comprising:
an insulative housing;
a pair of conductive leads each having a portion embedded into the insulative housing and another portion exposed out of the housing;
the another portion bent three times to form an end portion, a bottom soldering portion, and a pair of side soldering portions, in turn.

6. The LED lead frame as claimed in claim 5, wherein a pair of tabs extend from two opposite sides of the end portion and each is formed with a slot with the respective side soldering portion.

7. The LED lead frame as claimed in claim 5, wherein a curved portion is formed between the side soldering portion and the bottom soldering portion, and the curved portion from the highest to the lowest point having a height is between 0.1-0.3 millimeter.

8. The LED lead frame as claimed in claim 5, wherein the insulative housing includes four side surfaces, a top surface, and a bottom surface, wherein a first and a third side surfaces are located at a longitudinal direction and a second and a fourth side surfaces are located at a traversal direction.

9. The LED lead frame as claimed in claim 8, wherein the bottom soldering portion is located at the bottom surface and extends along the traversal direction.

10. The LED lead frame as claimed in claim 8, wherein the pair of side soldering portions of the conductive lead extend upwardly along the second and the fourth side surfaces, respectively.

11. An LED lead frame comprising:
an insulative housing defining a rectangular body with a pair of opposite side surfaces in a transverse direction, a pair of opposite end surfaces in a longitudinal direction perpendicular to said transverse direction and a pair of opposite upper and bottom surfaces in a vertical direction perpendicular to both said transverse direction and said longitudinal direction, under condition that each of said upper and bottom surfaces is defined by a long side extending along said longitudinal direction, and a short side extending along said transverse direction;
a cavity recessed downwardly from the upper surface while upwardly spaced from the bottom surface in the vertical direction;
a pair of conductive leads integrally formed with the housing, each of the pair of conductive leads defining an upstanding U-shaped soldering section which is located around one end of the housing in the longitudinal direction, a horizontal contacting section essentially extending along the longitudinal direction toward while being spaced from the other conductive lead around a bottom face of the cavity, and a lying U-shaped structure linked between the upstanding U-shaped soldering section and the horizontal contacting section.

12. The LED frame as claimed in claim 11, wherein the lying U-shaped structure covers the corresponding end surface.

13. The LED frame as claimed in claim 11, wherein the upstanding U-shaped soldering section is exposed to an exterior to cover portions of the corresponding bottom surface and side surfaces.

14. The LED frame as claimed in claimed 11, wherein the horizontal contacting section of one of the pair of conductive leads is longer than that of the other of the pair of conductive leads.

15. The LED frame as claimed in claim 11, wherein the lying U-shaped structure of each of the pair of conductive leads defines therein a through slot which allows the corresponding end surface to be exposed toward an exterior.

16. The LED frame as claimed in claim 15, wherein said through slots further extends into the corresponding horizontal contacting section to enhance binding between the housing and the conductive lead.

17. The LED frame as claimed in claim 11, wherein either the lying U-shaped structure or the upstanding U-shaped soldering section defines a transversely protrusion extending toward the other at a level between the bottom surface of the housing and the bottom face of the cavity.

18. The LED frame as claimed in claim 17, wherein said protrusion is formed on the lying U-shaped structure and extends along the transverse direction.

19. The LED frame as claimed in claim 11, wherein the horizontal contacting section defines a protrusion and recess structure to enhance retention between the housing and the corresponding conductive lead.
